(19) United States
(12) Patent Application Publication
(10) Pub. No.: US 2012/0312232 A1
(43) Pub. Date: Dec. 13, 2012

(54) INLINE DEPOSITION APPARATUS

(76) Inventors: Seung-Hun Kim, Yongin-city (KR); Sang-Joon Seo, Yongin-city (KR); Jin-Kwang Kim, Yongin-city (KR); Jun-Hyuk Cheon, Yongin-city (KR)

(21) Appl. No.: 13/313,978

(22) Filed: Dec. 7, 2011

(30) Foreign Application Priority Data
Jun. 10, 2011 (KR) 10-2011-0056287

(51) Int. Cl. C23C 16/455

(52) U.S. Cl. 118/722; 118/715

(57) ABSTRACT

An inline deposition apparatus includes a chamber; a loading unit inside the chamber and loaded with an object to be processed to be moved in a first direction; a plurality of first deposition modules in the chamber for depositing a first layer to the object to be processed; and a plurality of second deposition modules in the chamber for depositing a second layer to the object to be processed, wherein at least one of the plurality of second deposition modules is positioned between neighboring first deposition modules, and wherein the first layer is different from the second layer.

### CROSS-REFERENCE TO RELATED APPLICATION

This application claims priority to and the benefit of Korean Patent Application No. 10-2011-0056287, filed in the Korean Intellectual Property Office on Jun. 10, 2011, the entire contents of which is incorporated herein by reference.

### BACKGROUND

1. Field

The present invention relates to an inline deposition apparatus. More particularly, the present invention relates to an inline deposition apparatus for depositing an atomic layer and a molecular layer to an object to be processed.

2. Description of Related Art

An inline deposition apparatus is an apparatus for depositing a plurality of layers to an object to be processed, such as an atomic layer or a molecular layer, through a plurality of deposition modules.

In a process for depositing the atomic layer or the molecular layer to the object to be processed by using the inline deposition apparatus, after supplying a source gas, including a source precursor, to the object to be processed, a purge gas is supplied to the object to be processed to purge the source precursor that is absorbed to the object to be processed. A reaction gas, including a reactant precursor reacting with the source precursor, is supplied to the object to be processed, and then the purge gas is supplied to the object to be processed thereby purging the remaining source precursor after the reaction and the reactant precursor.

Recently, an inline deposition apparatus has been developed that disposes a plurality of atomic layer deposition modules for depositing the atomic layer and a plurality of molecular layer deposition modules depositing the molecular layer inside one chamber. The object to be processed is then transferred under a plurality of atomic layer deposition modules and a plurality of molecular layer deposition modules, and a plurality of atomic layers or a plurality of molecular layers are sequentially deposited to the object to be processed.

However, in the conventional inline deposition apparatus, the neighboring atomic layer deposition modules among a plurality of atomic layer deposition modules are close to each other and the neighboring molecular layer deposition modules among a plurality of molecular layer deposition modules are close to each other. Accordingly, a purge time required between the previous deposition module among and the subsequent deposition module among the neighboring deposition modules may not be sufficient. That is, a remaining amount of source gas supplied to the object to be processed in the previous deposition module is reacted with the reaction gas supplied to the next deposition module, resulting in the quality of the atomic layer or the molecular layer deposited to the object to be processed being deteriorated. This problem is frequently generated when the transferring time of the object to be processed for a plurality of deposition modules is shortened.

The above information disclosed in this Background section is only for enhancement of understanding of the background of the invention and therefore it may contain information that does not form the prior art that is already known in this country to a person of ordinary skill in the art.

### SUMMARY

An exemplary embodiment of the present invention provides an inline deposition apparatus that minimizes or reduces quality deterioration of the atomic layer or the molecular layer deposited to the object to be processed even though the atomic layer or the molecular layer is sequentially formed to the object to be processed by using a plurality of depositions.

To obtain the above benefits, an inline deposition apparatus includes: a chamber; a loading unit positioned inside the chamber, and loaded with an object to be processed to be moved in a first direction; a plurality of first deposition modules arranged along the first direction in the chamber for depositing a first layer to the object to be processed; and a plurality of second deposition modules arranged along the first direction in the chamber for depositing a second layer to the object to be processed, wherein at least one of the plurality of second deposition modules is between neighboring first deposition modules, and wherein the first layer is different from the second layer.

One of the first layer and the second layer may be an atomic layer and the other of the first layer and the second layer may be a molecular layer.

The first deposition module may include: a first supplying unit for supplying a first source gas and a first reaction gas to the object to be processed; a first purge supplying unit for supplying a purge gas to the object to be processed; and a first purge exhausting unit for exhausting the purge gas.

The second deposition module may include: a second supplying unit for supplying a second source gas and a second reaction gas to the object to be processed; a second purge supplying unit for supplying the purge gas to the object to be processed; and a second purge exhausting unit for exhausting the purge gas.

The purge gas may be further exhausted through the first supplying unit or the second supplying unit.

One of the first deposition modules may be isolated with the object to be processed when depositing the first layer to the object to be processed, and one of the second deposition modules may be isolated with the object to be processed when depositing the second layer to the object to be processed.

According to one exemplary embodiment, even though the atomic layers and the molecular layers are sequentially formed to the object to be processed through a plurality of depositions, quality deterioration of the atomic layer or the molecular layer deposited to the object to be processed is minimized or reduced.

### BRIEF DESCRIPTION OF THE DRAWINGS

FIG. 1 is a schematic view of an inline deposition apparatus according to the first exemplary embodiment of the present invention.

FIG. 2 is a detailed view of a portion A of FIG. 1.

FIG. 3 is a schematic view of a deposition method using an inline deposition apparatus according to the first exemplary embodiment of the present invention.

FIG. 4 is a schematic view of an inline deposition apparatus according to the second exemplary embodiment of the present invention.

### DETAILED DESCRIPTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

Descriptions of parts not related to the present invention may be omitted, and like reference numerals designate like elements throughout the specification. Further, only those elements of other embodiments that are different from those of the first embodiment may be described.

In the drawings, the size and thickness of each element may be approximately shown for better understanding and ease of description. Therefore, the present invention is not limited to the drawings. In the drawings, the thickness of layers, films, panels, regions, etc., may be exaggerated for clarity. Further, in the drawings, the thicknesses of layers and regions may be exaggerated for better understanding and ease of description. It will be understood that when an element such as a layer, film, region, or substrate is referred to as being “on” another element, it can be directly on the other element or intervening elements may also be present. Further, throughout the specification, “on” implies being positioned above or below a target element and does not imply being necessarily positioned on the top on the basis of a gravity direction.

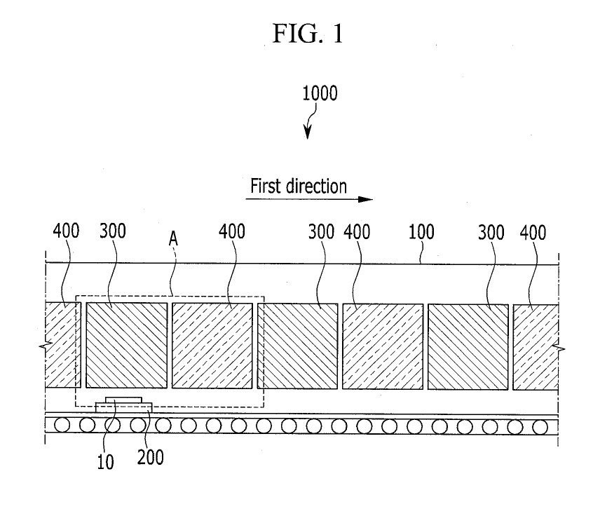

In addition, unless explicitly described to the contrary, the word “comprise” and variations such as “comprises” or “comprising” will be understood to imply the inclusion of stated elements but not the exclusion of any other elements. Now, an inline deposition apparatus according to the first exemplary embodiment of the present invention will be described with reference to FIG. 1 to FIG. 4.

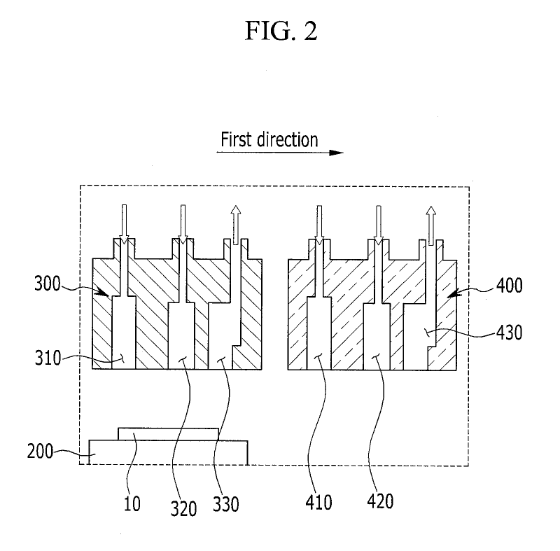

FIG. 1 is a schematic view of an inline deposition apparatus according to the first exemplary embodiment of the present invention. FIG. 2 is a detailed view of a portion A of FIG. 1.

As shown in FIG. 1 and FIG. 2, an inline deposition apparatus 1000 according to the first exemplary embodiment of the present invention includes a chamber 100, a loading unit 200, a plurality of first deposition modules 300, and a plurality of second deposition modules 400.

The chamber 100 may be in a vacuum state, and the chamber 100 may be connected to a vacuum pump such as a turbomolecular pump (TMP) to maintain the vacuum state. Also, a predetermined material may be filled in the chamber 100. The loading unit 200, the plurality of first deposition modules 300, and the plurality of second deposition modules 400 are positioned in the chamber 100.

The loading unit 200 is positioned inside the chamber 100, and an object to be processed 10 is loaded and moved in a direction, e.g., the first direction. The loading unit 200 is supported by a roller and a rail, and is transferred and guided by the roller to move in the first direction. While the loading unit 200 is moved in the first direction, the object to be processed 10 loaded on the loading unit 200 passes under a plurality of first deposition modules 300 and a plurality of second deposition modules 400. As it is passed under the first and second deposition modules 300, 400, at least one of a first layer and a second layer is sequentially deposited to the object to be processed 10 through the plurality of first deposition modules 300 and the plurality of second deposition modules 400. Here, one of the first layer and the second layer may be an atomic layer and the other thereof may be a molecular layer. For ease of description, the description with be made with references to the first layer as the atomic layer and the second layer as the molecular layer.

The plurality of first deposition modules 300 are arranged along the first direction in the chamber 100, and the atomic layer as the first layer is deposited to the object to be processed 10. Neighboring first deposition modules 300 among a plurality of first deposition modules 300 are separated from each other via second deposition modules 400 interposed therebetween. The first deposition module 300 includes a first supplying unit 310, a first purge supplying unit 320, and a first purge exhausting unit 330.

The first supplying unit 310 forms a path for selectively supplying the first source gas and the first reaction gas to the object to be processed 10 while it passes under the first deposition module 300. The first source gas includes a source precursor to deposit the atomic layer, and the first reaction gas includes a reactant precursor to deposit the atomic layer. The source precursor included in the first source gas may be a material capable of forming the atomic layer to the object to be processed 10 by reacting with the reactant precursor included in the first reaction gas. The type of source precursor may vary according to the kind of the atomic layer to be formed to the object to be processed 10. For example, the source precursor may include at least one of an IV group element based compound, an III-V group element based compound, an II-VI group element based compound, a Ni-based compound, a Co-based compound, an Al-based compound, a Ti-based compound, a Hf-based compound, a Zr-based compound, a Ta-based compound, a Mo-based compound, a W-based compound, a Si-based compound, a Zn-based compound, a Cu-based compound, or a Co-based compound. Also, the reactant precursor may be a material capable of forming the atomic layer to the object to be processed 10, and may vary according to the type of atomic layer. For example, the reactant precursor may include at least one of H₂O, H₂O₂, O₂, N₂O, O₃, an O* radical, NH₃, NH₂—NH₂, N₂, a N* radical, an organic carbon compound, such as CH₄ or C₂H₆, H₂, and a H* radical.

The first purge supplying unit 320 has a path for supplying a purge gas to the object to be processed 10. The purge gas may include an inert material such as N₂, Ar, or He.

The first purge exhausting unit 330 has a path through which the purge gas and the material detached from the object to be processed 10 by the purge gas is exhausted.

A plurality of the first deposition modules 300 are respectively separated (or isolated) together with the object to be processed 10 when depositing the atomic layer of the first layer to the object to be processed 10, and this separation or isolation may be executed by using air or a barrier rib as a method and/or structure for separation.

The purge gas and the material detached from the object to be processed 10 by the purge gas may also be exhausted through the first supplying unit 310.

At least a plurality of the second deposition modules 400 are positioned between neighboring first deposition modules 300 among a plurality of the first positioned modules 300 in the chamber 100, and they deposit the molecular layer of the second layer to the object to be processed 10. Neighboring second deposition modules 400 of the plurality of second deposition modules 400 are separated by and positioned between the first deposition module 300. That is, a plurality of the first deposition modules and a plurality of the second deposition modules are alternatively positioned. The second deposition module 400 includes a second supplying unit 410, a second purge supplying unit 420, and a second purge exhausting unit 430.

The second supplying unit 410 has a path for selectively supplying the second source gas and the second reaction gas to the object to be processed 10 when it passes under the second deposition module 400. The second source gas includes the source precursor to deposit the molecular layer, and the second reaction gas includes the reactant precursor to deposit the molecular layer. The source precursor included in the second source gas may be a material capable of forming the molecular layer to the object to be processed 10 by reacting with the reactant precursor included in the second reaction gas.

The second purge supplying unit 420 has a path for supplying the purge gas to the object to be processed 10, and the second purge exhausting unit 430 has a path for exhausting the purge gas and the material detached from the object to be processed 10 by the purge gas.

A plurality of second deposition modules 400 are respectively separated (or isolated) together with the object to be processed 10 when depositing the molecular layer of the second layer to the object to be processed 10, and this separation may be executed by using air or a barrier rib as a method and/or structure for separation.

The purge gas and the material detached from the object to be processed 10 by the purge gas may also be exhausted through the second supplying unit 410.

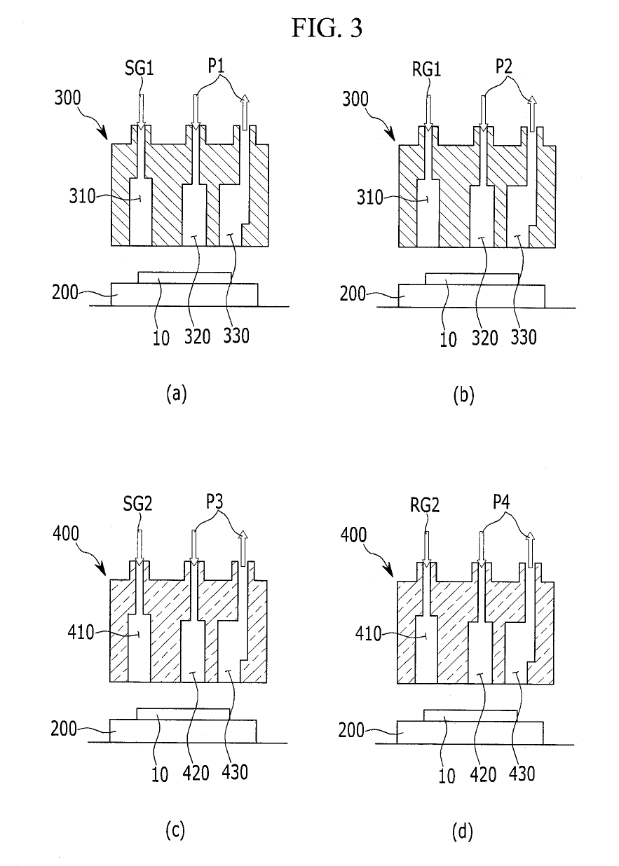

Next, a deposition executing method using an inline deposition apparatus according to the first exemplary embodiment of the present invention will be described with reference to FIG. 3.

FIG. 3 is a schematic view showing a deposition executing method using an inline deposition apparatus according to the first exemplary embodiment of the present invention.

Firstly, as shown in FIG. 3 (a), the object to be processed 10 is positioned under the first deposition module 300 by the loading unit 200. After the first deposition module 300 is separated (or isolated) together with the object to be processed 10, the first deposition module 300 supplies the first source gas SG1 to form the atomic layer to the object to be processed 10 through the first supplying unit 310 to absorb the source precursor to the object to be processed 10. The first deposition module 300 then supplies the first purge gas P1 to the object to be processed 10 through the first purge supplying unit 320, and exhausts the remaining source precursor after the absorption to the object to be processed 10 through the first purge exhausting unit 330 and the first purge gas P1.

Next, as shown in FIG. 3 (b), the first deposition module 300 supplies the first reaction gas RG1 to form the atomic layer to the object to be processed 10 through the first supplying unit 310 to react the source precursor absorbed to the object to be processed 10 and the reactant precursor and to form the atomic layer of the first layer to the object to be processed 10. The first deposition module then supplies the second purge gas P2 to the object to be processed 10 through the first purge supplying unit 320, and exhausts the remaining reactant precursor after the reaction for the source precursor and the second purge gas P2 through the first purge exhausting unit 330.

Next, as shown in FIG. 3 (c), the loading unit 200 is moved in the first direction such that the object to be processed 10 is positioned under the second deposition module 400. After the second deposition module 400 is separated (or isolated) together with the object to be processed 10, the second deposition module 400 supplies the second source gas SG2 to form the molecular layer to the object to be processed 10 through the second supplying unit 410 to absorb the source precursor to the object to be processed 10. The second deposition unit 400 then supplies the third purge gas P3 to the object to be processed 10 through the second purge supplying unit 420, and exhausts the remaining source precursor after the absorption to the object to be processed 10 and the third purge gas P3 through the second purge exhausting unit 430. Here, the source precursor and the reactant precursor that are supplied from the first deposition module 300 to the object to be processed 10 and remain on the object to be processed 10 (in relation to the formation of the atomic layer) are exhausted along with the third purge gas P3 through the second purge exhausting unit 430. On the other hand, the source precursor and the reactant precursor in relation to the formation of the atomic layer may also be exhausted along with the third purge gas P3 through the second supplying unit 410.

Next, as shown in FIG. 3 (d), the second deposition module 400 supplies the second reaction gas RG2 for formation of the molecular layer to the object to be processed 10 through the second supplying unit 410 to react the source precursor absorbed to the object to be processed 10 and the reactant precursor and to form the molecular layer of the second layer to the object to be processed 10. The second deposition module 400 then supplies the fourth purge gas P4 to the object to be processed 10 through the second purge supplying unit 420, and exhausts the reactant precursor after the reaction along with the source precursor and the fourth purge gas P4 through the second purge exhausting unit 430.

Next, the loading unit 200 is moved in the first direction such that the object to be processed 10 is again positioned under the first deposition module 300. After the first deposition module 300 is separated (or isolated) together with the object to be processed 10, the first deposition module 300 supplies the first source gas SG1 for the formation of the atomic layer to the object to be processed 10 through the first supplying unit 310 to absorb the source precursor to the object to be processed 10. The first deposition module 300 then supplies the first purge gas P1 to the object to be processed 10 through the first purge supplying unit 320, and exhausts the source precursor remaining after the absorption to the object to be processed 10 and the first purge gas P1 through the first purge exhausting unit 330. Here, the source precursor and the reactant precursor that are supplied from the first deposition module 300 to the object to be processed 10 and remain on the object to be processed 10 (in relation to the formation of the molecular layer) are exhausted along with the first purge gas P1 through the first purge exhausting unit 330. On the other hand, the source precursor and the reactant precursor in relation to the formation of the molecular layer may also be exhausted along with the first purge gas P1 through the first supplying unit 310.

By repeating the above-described processes, the atomic layer and the molecular layer are sequentially deposited to the object to be processed 10.

As described above, although the inline deposition apparatus 1000 according to the first exemplary embodiment of the present invention sequentially deposits the atomic layer or the molecular layer to the object to be processed 10 through a plurality of depositions, the remaining materials related to the formation of the atomic layer executed in the first deposition module 300 are again purged by the purge executed in the second deposition module 400 such that the entire number of purges for the object to be processed 10 is increased. Accordingly, sufficient purge time for the object to be processed 10 is obtained such that formation of undesired particles or pin holes in the atomic layer formed to the object to be processed 10 is suppressed. Thereby, the quality deterioration of the atomic layer deposited to the object to be processed 10 may be minimized or reduced.

Also, although the inline deposition apparatus 1000 according to the first exemplary embodiment of the present invention sequentially deposits the atomic layer or the molecular layer to the object to be processed 10 through a plurality of depositions, the remaining materials related to the formation of the atomic layer executed in the second deposition module 400 are again purged by the purge executed in the first deposition module 300 such that the entire number of purges for the object to be processed 10 is increased. Accordingly, sufficient purge time for the object to be processed 10 is obtained such that formation of undesired particles or pin holes in the molecular layer formed to the object to be processed 10 is suppressed, and thereby the quality deterioration of the molecular layer deposited to the object to be processed 10 may be minimized or reduced.

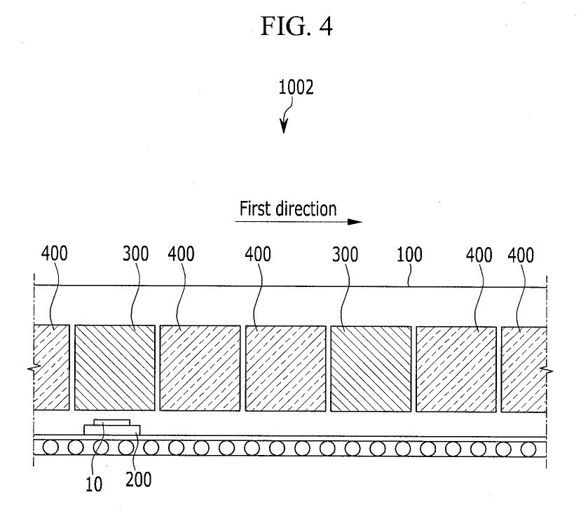

Next, an inline deposition apparatus according to the second exemplary embodiment of the present invention will be described with reference to FIG. 4.

FIG. 4 is a schematic view of an inline deposition apparatus according to the second exemplary embodiment of the present invention.

As shown in FIG. 4, in an inline deposition apparatus 1002 according to the second exemplary embodiment of the present invention, at least two of a plurality of second deposition modules 400 are positioned between neighboring first deposition modules 300 among a plurality of the first deposition modules 300. That is, a plurality of second deposition modules 400 are positioned between neighboring first deposition modules 300, and thereby a plurality of molecular layers are formed between the neighboring atomic layers deposited to the object to be processed 10, or only one deposition module of the neighboring plurality of second deposition modules 400 is used as a module for the purge for the object to be processed 10, to increase the purge time such that the quality deterioration of the atomic layer or molecular layer deposited to the object to be processed 10 is minimized or reduced.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims, and their equivalents.

### DESCRIPTION OF SELECTED REFERENCE NUMERALS

100: chamber
200: loading unit
300: first deposition module
400: second deposition module

What is claimed is:

1. An inline deposition apparatus comprising:
a chamber;
a loading unit positioned inside the chamber, and loaded with an object to be processed to be moved in a first direction;
a plurality of first deposition modules arranged along the first direction in the chamber for depositing a first layer to the object to be processed; and
a plurality of second deposition modules arranged along the first direction in the chamber for depositing a second layer to the object to be processed,
wherein at least one of the plurality of second deposition modules is between neighboring first deposition modules among the plurality of first deposition modules, and wherein the first layer is different from the second layer.

2. The inline deposition apparatus of claim 1, wherein
one of the first layer and the second layer is an atomic layer and the other of the first layer and the second layer is a molecular layer.

3. The inline deposition apparatus of claim 2, wherein
the first deposition module includes:
a first supplying unit for selectively supplying a first source gas and a first reaction gas to the object to be processed;
a first purge supplying unit for supplying a purge gas to the object to be processed; and
a first purge exhausting unit for exhausting the purge gas.

4. The inline deposition apparatus of claim 3, wherein
the second deposition module includes:
a second supplying unit for selectively supplying a second source gas and a second reaction gas to the object to be processed;
a second purge supplying unit for supplying the purge gas to the object to be processed; and
a second purge exhausting unit for exhausting the purge gas.

5. The inline deposition apparatus of claim 4, wherein
the purge gas is further exhausted through one of the first supplying unit and the second supplying unit.

6. The inline deposition apparatus of claim 1, wherein
one of the first deposition modules of the plurality of first deposition modules is isolated together with the object to be processed when depositing the first layer to the object to be processed, and
one of the second deposition modules of the plurality of second deposition modules is isolated together with the object to be processed when depositing the second layer to the object to be processed.
